(19) United States
(12) Patent Application Publication
(10) Pub. No.: US 2026/0101496 A1
(43) Pub. Date: Apr. 9, 2026

(54) SEMICONDUCTOR MEMORY DEVICE

(71) Applicant: Samsung Electronics Co., Ltd., Suwon-si (KR)

(72) Inventors: Gyuhwan Oh, Suwon-si (KR); Jinwoo Han, Suwon-si (KR); Yoonjae Kim, Suwon-si (KR); Jihoon Choi, Suwon-si (KR); Seunguk Han, Suwon-si (KR)

(21) Appl. No.: 19/281,192

(22) Filed: Jul. 25, 2025

(30) Foreign Application Priority Data
Oct. 7, 2024 (KR) 10-2024-0135967

(51) Int. Cl. H10B 12/00; H01L 23/00; H01L 25/065; H01L 25/18; H10B 80/00

(52) U.S. Cl. CPC H10B 12/30; H10B 12/03; H10B 12/05; H10B 80/00; H10W 90/00; H10W 90/792

(57) ABSTRACT

A semiconductor memory device including a first substrate, a semiconductor pattern disposed on the first substrate, first word lines disposed on the first substrate, first bit lines, second bit lines disposed above the first bit lines, select transistors, interposed between each of the first bit lines and each of the second bit lines, respectively, first wirings interposed between the first bit lines and the select transistors, respectively, and first upper wirings interposed between the select transistors and the second bit lines, respectively, wherein each of the select transistors includes a plurality of first vertical channels.

### CROSS-REFERENCE TO RELATED APPLICATION

This application is based on and claims priority under 35 U.S.C. § 119 to Korean Patent Application No. 10-2024-0135967, filed on Oct. 7, 2024, in the Korean Intellectual Property Office, the disclosure of which is incorporated by reference herein in its entirety.

### BACKGROUND

The inventive concept relates to a semiconductor memory device, and more particularly, to a three-dimensional semiconductor memory device including a plurality of memory cells that are arranged three-dimensionally.

Along with the demand for the miniaturization, multi-functionality, and high performance of electronic products, high-capacity semiconductor memory devices are in demand, and to provide high-capacity semiconductor memory devices, an increased degree of integration is needed. Three-dimensional semiconductor memory devices in which a plurality of memory cells are stacked on a substrate in a vertical direction to increase memory capacity have been proposed.

### SUMMARY

Aspects of the inventive concept provide a semiconductor memory device having improved integration and excellent operation reliability.

According to an aspect of the inventive concept, there is provided a semiconductor memory device including a first substrate, a semiconductor pattern disposed on the first substrate and extending in a first horizontal direction parallel to an upper surface of the first substrate, a plurality of first word lines disposed on the first substrate and spaced apart from each other in a vertical direction, a plurality of first bit lines extending lengthwise in the vertical direction, and the first bit lines spaced apart from each other in a second horizontal direction intersecting the first horizontal direction, a plurality of second bit lines disposed above the plurality of first bit lines, the second bit line extending in the first horizontal direction and spaced apart from each other in the second horizontal direction, a plurality of select transistors, each of the select transistors interposed between a respective first bit line of the plurality of first bit lines and a respective second bit line of the plurality of second bit lines and spaced apart from each other in the second horizontal direction, a plurality of first wirings, each of the first wirings interposed between a respective first bit line of the plurality of first bit lines and a respective select transistor of the plurality of select transistors, and a plurality of first upper wirings interposed between the plurality of select transistors and the plurality of second bit lines, with each of the first wirings interposed between a respective one of the first bit lines and a respective one of the select transistors, wherein each of the select transistors includes a plurality of first vertical channels.

According to another aspect of the inventive concept, there is provided a semiconductor memory device including a first substrate, a semiconductor pattern disposed on the first substrate and extending in a first horizontal direction parallel to an upper surface of the first substrate, a plurality of first word lines disposed on the first substrate and the first word lines spaced apart from each other in a vertical direction, a plurality of first bit lines extending in the vertical direction and the first bit lines spaced apart from each other in a second horizontal direction intersecting the first horizontal direction, a plurality of second bit lines disposed above the plurality of first bit lines, extending in the first horizontal direction, and the second bit lines spaced apart from each other in the second horizontal direction, a plurality of select transistors, each of the select transistors interposed between a respective first bit line of the plurality of first bit lines and a respective second bit line of the plurality of second bit lines and spaced apart from each other in the second horizontal direction, a plurality of keeper transistors, each of the keeper transistors interposed between a respective first bit line of the plurality of first bit lines and a respective second bit line of the plurality of second bit lines and spaced apart from each other in the second horizontal direction, a plurality of first wirings, each of the first wirings interposed between a respective first bit line of the plurality of first bit lines and a respective select transistor of the plurality of select transistors and between a respective first bit line of the plurality of first bit lines and a respective keeper transistor of the plurality of keeper transistors, a plurality of first upper wirings with each of the first upper wirings interposed between a respective select transistor of the plurality of select transistors and a respective second bit line of the plurality of second bit lines, and a plurality of second upper wirings, each of the second upper wirings interposed between a respective keeper transistor of the plurality of keeper transistors and a respective second bit line of the plurality of second bit lines, wherein each of the select transistors includes a plurality of first vertical channels, and each of the keeper transistors includes a plurality of second vertical channels.

According to another aspect of the inventive concept, there is provided a semiconductor memory device including a cell structure and a peripheral circuit structure disposed on the cell structure and bonded to the cell structure, wherein the cell structure includes a first substrate, a semiconductor pattern disposed on the first substrate and extending in a first horizontal direction parallel to an upper surface of the first substrate, a plurality of first word lines disposed on the first substrate and the first word lines spaced apart from each other in a vertical direction, a plurality of first bit lines extending in the vertical direction and the first bit lines spaced apart from each other in a second horizontal direction intersecting the first horizontal direction, a plurality of second bit lines disposed above the plurality of first bit lines, extending in the first horizontal direction, and the second bit lines spaced apart from each other in the second horizontal direction, a plurality of select transistors, each of the select transistors interposed between a respective first bit line of the plurality of first bit lines and a respective second bit line of the plurality of second bit lines, a plurality of keeper transistors, each of the keeper transistors interposed between a respective first bit line of the plurality of first bit lines and a respective second bit line of the plurality of second bit lines and spaced apart from each of the select transistors in the first horizontal direction, a plurality of first wirings, each of the first wirings interposed between a respective first bit line of the plurality of first bit lines and a respective select transistor of the plurality of select transistors, respectively, and between the plurality of first bit lines and the plurality of keeper transistors, a plurality of first upper wirings, each of the first upper wirings interposed between a respective select transistor of the plurality of select transistors and a respective second bit line of the plurality of second bit lines, a plurality of second upper wirings, each of the second upper wirings interposed between a respective keeper transistor of the plurality of keeper transistors and a respective second bit line of the plurality of second bit lines, a plurality of second wirings, each second wiring disposed on a respective first upper wiring of the plurality of first upper wirings and electrically connected to a respective second bit line of the plurality of second bit lines, a third wiring disposed on the plurality of second upper wirings and electrically isolated from the plurality of second bit lines, and an upper wiring structure disposed on the plurality of second bit lines, wherein each of the select transistors includes a plurality of first vertical channels, and each of the keeper transistors includes a plurality of second vertical channels.

### BRIEF DESCRIPTION OF THE DRAWINGS

Embodiments of the inventive concept will be more clearly understood from the following detailed description taken in conjunction with the accompanying drawings in which:

FIG. 1 is a perspective view schematically illustrating a semiconductor memory device according to embodiments;

FIG. 2 is a cross-sectional view taken along line A1-A1′ of FIG. 1;

FIG. 3 is an enlarged cross-sectional view of portion EX1 of FIG. 2;

FIG. 4 is a cross-sectional view illustrating a semiconductor memory device according to embodiments;

FIG. 5 is an enlarged cross-sectional view of portion CX1 of FIG. 4;

FIG. 6 is a top view schematically illustrating a semiconductor memory device according to embodiments;

FIG. 7 is an enlarged top view of portion EX2 of FIG. 6;

FIG. 8 is a cross-sectional view illustrating an operation of a semiconductor memory device according to embodiments;

FIG. 9 is a perspective view schematically illustrating a semiconductor memory device according to embodiments;

FIG. 10 is a cross-sectional view taken along line A2-A2′ of FIG. 9; and

FIGS. 11 to 18 are cross-sectional views illustrating a method of manufacturing a semiconductor memory device, according to embodiments.

### DETAILED DESCRIPTION OF THE EMBODIMENTS

Hereinafter, the present disclosure will be described more fully with reference to the accompanying drawings, in which various embodiments are described. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

Like reference numerals in the drawings denote like elements, and when the repeated description thereof would be redundant, such description may be omitted.

Throughout the specification, when a component is described as “including” a particular element or group of elements, it is to be understood that the component may be formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two devices, an electrically insulative underfill or mold layer, etc.) is not electrically connected to that component. Moreover, items that are “directly electrically connected,” to each other are electrically connected through one or more passive elements, such as, for example, wires, pads, internal electrical lines, through vias, etc. As such, directly electrically connected components do not include components electrically connected through active elements, such as transistors or diodes. Directly electrically connected elements may be directly physically connected and directly electrically connected.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially”may be used herein to emphasize this meaning.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Items described in the singular herein may be provided in plural, as can be seen, for example, in the drawings. Thus, the description of a single item that is provided in plural should be understood to be applicable to the remaining plurality of items unless context indicates otherwise.

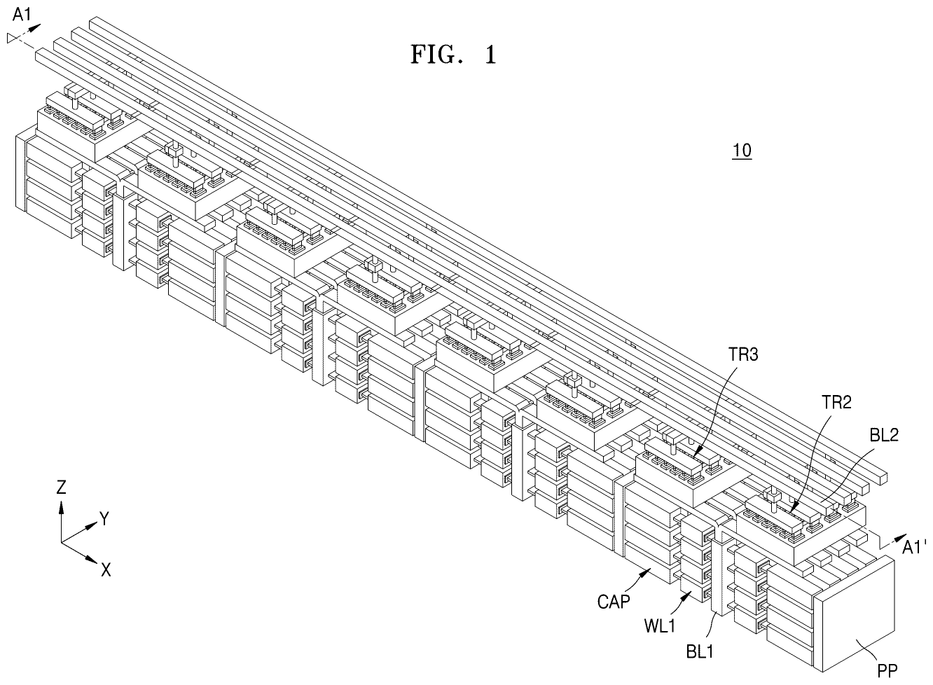

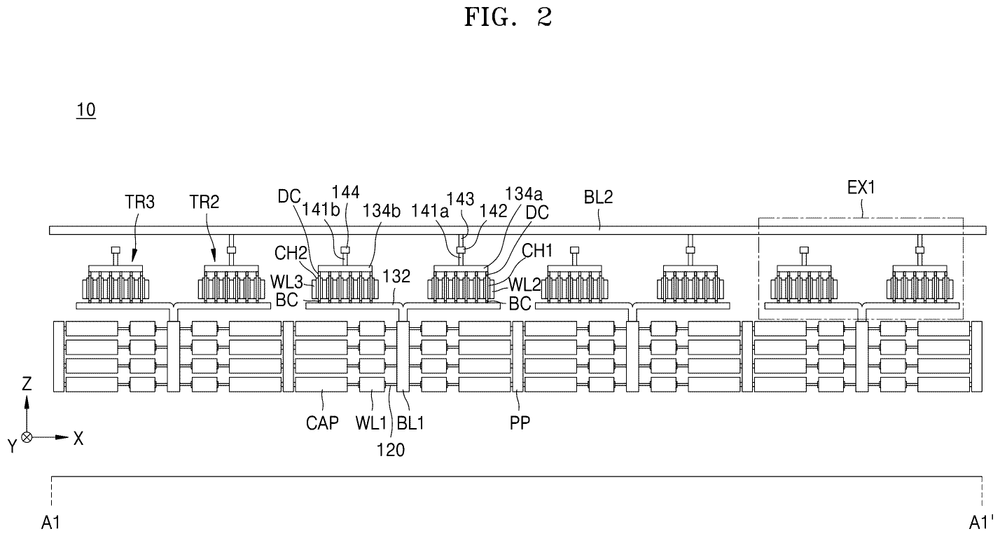

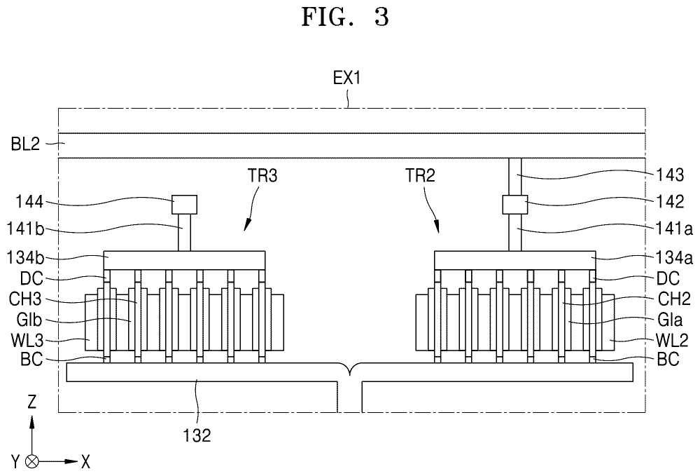

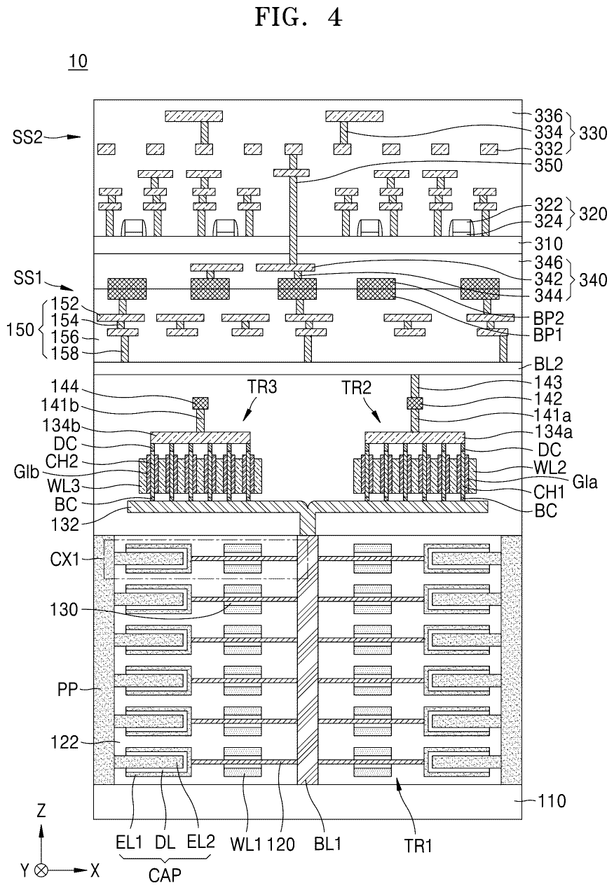

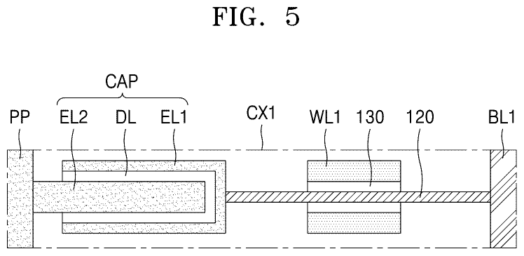

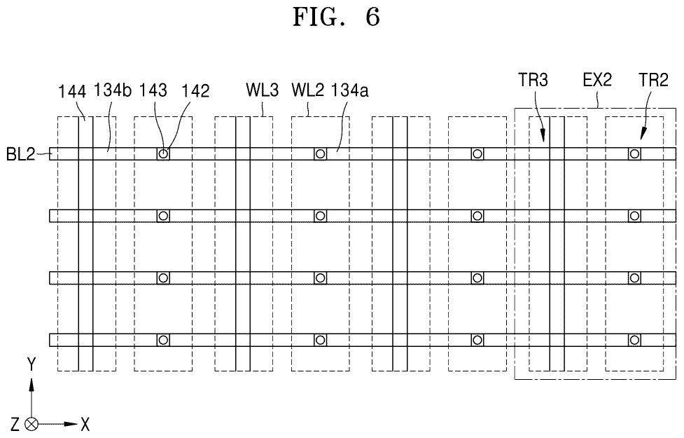

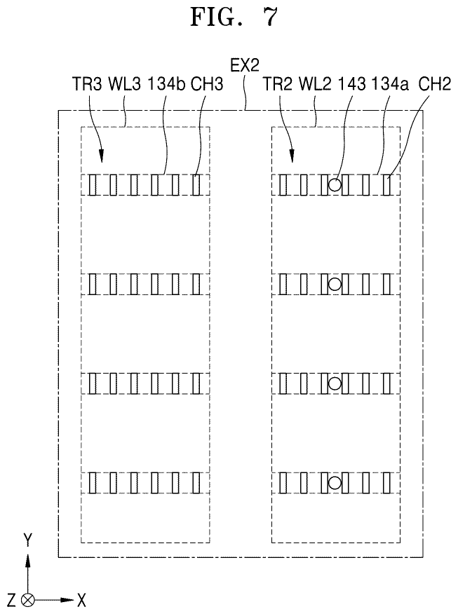

FIG. 1 is a perspective view schematically illustrating a semiconductor memory device 10 according to embodiments. FIG. 2 is a cross-sectional view taken along line A1-A1′ of FIG. 1. FIG. 3 is an enlarged cross-sectional view of portion EX1 of FIG. 2. FIG. 4 is a cross-sectional view illustrating the semiconductor memory device 10 according to embodiments. FIG. 5 is an enlarged cross-sectional view of a portion CX1 of FIG. 4. FIG. 6 is a top view schematically illustrating the semiconductor memory device 10 according to embodiments. FIG. 7 is an enlarged top view of portion EX2 of FIG. 6. Particularly, FIGS. 1 and 2 schematically illustrate a cell structure SS1 (see FIG. 4) of the semiconductor memory device 10, FIG. 4 schematically illustrates a portion of the semiconductor memory device 10, and FIG. 6 schematically illustrates a portion of the cell structure SS1 of the semiconductor memory device 10.

Referring to FIGS. 1 to 7, the semiconductor memory device 10 may include the cell structure SS1 and a peripheral circuit structure SS2 on the cell structure SS1. The cell structure SS1 and the peripheral circuit structure SS2 may be bonded to each other by a first bonding pad BP1 and a second bonding pad BP2.

The cell structure SS1 may include a first substrate 110 and a plurality of semiconductor patterns 120, a plurality of first bit lines BL1, a plurality of first word lines WL1, and a plurality of cell capacitors CAP on the first substrate 110.

The first substrate 110 may include a semiconductor material, e.g., a group IV semiconductor, a group III-V compound semiconductor, or a group II-VI oxide semiconductor. For example, the group IV semiconductor may include silicon (Si), germanium (Ge), or SiGe. The first substrate 110 may be provided as a bulk wafer or an epitaxial layer. In an embodiment, the first substrate 110 may include a silicon on insulator (SOI) substrate or a germanium on insulator (GeOI) substrate.

On the first substrate 110, the plurality of semiconductor patterns 120 may extend lengthwise in a first horizontal direction (the X direction) and be spaced apart from each other in the vertical direction (the Z direction).

In embodiments, the plurality of semiconductor patterns 120 may have a line or bar shape extending in the first horizontal direction (the X direction).

In embodiments, each of the plurality of semiconductor patterns 120 may be formed of, for example, an undoped semiconductor material or a doped semiconductor material. In some embodiments, each of the plurality of semiconductor patterns 120 may be formed of polysilicon. In some embodiments, each of the plurality of semiconductor patterns 120 may include amorphous metal oxide, polycrystalline metal oxide, a combination thereof, or the like, and for example, include at least one of indium (In)-gallium (Ga)-based oxide (IGO), In-zinc (Zn)-based oxide (IZO), and In-Ga-Zn-based oxide (IGZO). In some embodiments, each of the plurality of semiconductor patterns 120 may include a two-dimensional (2D) material semiconductor, and for example, the 2D material semiconductor may include molybdenum disulfide (MoS₂), tungsten diselenide (WSe₂), graphene, a carbon nanotube, or a combination thereof.

The plurality of first word lines WL1 may be on the first substrate 110 and spaced apart from each other in the vertical direction (the Z direction) and the first horizontal direction (the X direction). The plurality of first word lines WL1 spaced apart from each other in the vertical direction (the Z direction) may be arranged in a stair shape in a second horizontal direction (the Y direction).

In embodiments, each of the plurality of first word lines WL1 may include titanium (Ti), titanium nitride (TiN), tantalum (Ta), tantalum nitride (TaN), tungsten (W), tungsten nitride (WN), titanium silicon nitride (TiSiN), tungsten silicon nitride (WSiN), polysilicon, or a combination thereof.

A gate insulating layer 130 may be between a first word line WL1 and a semiconductor pattern 120. In embodiments, the gate insulating layer 130 may be formed of at least one selected from a high-k dielectric material, which has a higher dielectric constant than silicon oxide, and a ferroelectric material. In some embodiments, the gate insulating layer 130 may be formed of at least one material selected from among hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (SBT), bismuth ferric oxide (BFO), strontium titanium oxide (SrTiO), yttrium oxide (YO), aluminum oxide (AlO), and lead scandium tantalum oxide (PbScTaO).

The plurality of first bit lines BL1 may extend lengthwise on the first substrate 110 in the vertical direction (the Z direction) and be spaced apart from each other in the second horizontal direction (the Y direction). The plurality of first word lines WL1 spaced apart from each other in the first horizontal direction (the X direction) may be spaced apart from each other in the first horizontal direction (the X direction) with a corresponding first bit line BL1 between neighboring first word lines WL1. The plurality of first bit lines BL1 may include any one of a doped semiconductor material, conductive metal nitride, a metal, and a metal-semiconductor compound. The first bit line BL1 may be referred to as a local bit line.

The plurality of cell capacitors CAP may be on the first substrate 110, extend in the first horizontal direction (the X direction), and be spaced apart from each other in the vertical direction (the Z direction) and the second horizontal direction (the Y direction). A cell capacitor CAP may be between a corresponding first word line WL1 and a plate electrode PP, which will be described below, in the first horizontal direction (the X direction).

The cell capacitor CAP may include a first electrode EL1, a capacitor dielectric layer DL, and a second electrode EL2. First electrodes EL1 may extend in the first horizontal direction (the X direction) and be spaced apart from each other in the vertical direction (the Z direction). The first electrode EL1 may have a cup shape with the opening oriented in a horizontal direction (e.g., the X direction). The first electrode EL1 may have an internal space (not shown) extending in the first horizontal direction (the X direction). The second electrode EL2 may fill the internal space of the first electrode EL1, and the capacitor dielectric layer DL may be between the first electrode EL1 and the second electrode EL2 (e.g., may fill the internal space of the first electrode around the second electrode).

In embodiments, the capacitor dielectric layer DL may be formed of at least one material selected from among a high-k dielectric material, which has a higher dielectric constant than silicon oxide, and a ferroelectric material. In some embodiments, the capacitor dielectric layer DL may be formed of at least one material selected from among HfO, HfSiO, HfON, HfSiON, LaO, LaAlO, ZrO, ZrSiO, ZrON, ZrSiON, TaO, TiO, BaSrTiO, BaTiO, PZT, SBT, BFO, SrTiO, YO, AlO, and PbScTaO.

In embodiments, each of the first electrode EL1 and the second electrode EL2 may include a doped semiconductor material, conductive metal nitride, such as TiN, TaN, niobium nitride, or WN, a metal, such as ruthenium, iridium, Ti, or Ta, or conductive metal oxide, such as iridium oxide or niobium oxide.

A cell transistor TR1 may be between the first bit line BL1 and the first word line WL1. The gate of the cell transistor TR1 may be connected to the first word line WL1, the source of the cell transistor TR1 may be connected to the first bit line BL1, and the drain of the cell transistor TR1 may be connected to the cell capacitor CAP. One cell transistor TR1 and one cell capacitor CAP may constitute one memory cell.

The plate electrode PP may be at a first side of the cell capacitor CAP. The plate electrode PP may extend in the vertical direction (the Z direction) and the second horizontal direction (the Y direction). The second electrode EL2 of the cell capacitor CAP may be electrically connected to the plate electrode PP. For example, a plurality of second electrodes EL2 spaced apart from each other in the vertical direction (the Z direction) and a plurality of second electrodes EL2 spaced apart from each other in the second horizontal direction (the Y direction) may be commonly connected to one plate electrode PP.

A mold insulating layer 122 may be between two adjacent semiconductor patterns 120 spaced apart from each other in the vertical direction (the Z direction), two adjacent first word lines WL1 spaced apart from each other in the vertical direction (the Z direction), and two adjacent first electrodes EL1 spaced apart from each other in the vertical direction (the Z direction). In addition, the mold insulating layer 122 may also be between two adjacent first bit lines BL1 spaced apart from each other in the second horizontal direction (the Y direction).

In embodiments, the mold insulating layer 122 may include silicon oxide, silicon oxynitride, silicon nitride, carbon-containing silicon oxide, carbon-containing silicon oxynitride, carbon-containing silicon nitride, or a combination thereof. In embodiments, the mold insulating layer 122 may include a plurality of insulating layers. In the specification, insulating material layers formed between the plurality of first bit lines BL1, between the plurality of first word lines WL1, between the plurality of semiconductor patterns 120, and between the plurality of cell capacitors CAP according to a manufacturing process employed to form a three-dimensional structure may be collectively referred to as the mold insulating layer 122.

A plurality of first wirings 132 may be on the plurality of first bit lines BL1, respectively. The plurality of first wirings 132 may overlap the plurality of first bit lines BL1 in the vertical direction (the Z direction), respectively. Each first wiring 132 may be connected to a corresponding first bit line BL1 among the plurality of first bit lines BL1.

A plurality of first vertical channels CH1 and a plurality of second vertical channels CH2 may be on each first wiring 132. Each of the plurality of first vertical channels CH1 and each of the plurality of second vertical channels CH2 may extend in the vertical direction (the Z direction). The plurality of first vertical channels CH1 on one first wiring 132 may form one first vertical channel group and the first vertical channels CH1 of a first vertical channel group may be spaced apart from each other in the first horizontal direction (the X direction). The plurality of second vertical channels CH2 on one first wiring 132 may form one second vertical channel group and the second vertical channels CH2 of a second vertical channel group may be spaced apart from each other in the first horizontal direction (the X direction).

The one first vertical channel group and the one second vertical channel group on the one first wiring 132 may be spaced apart from each other in the first horizontal direction (the X direction).

A plurality of first vertical channel groups respectively on the plurality of first wirings 132 may be spaced apart from each other in the second horizontal direction (the Y direction), and a plurality of second vertical channel groups respectively on the plurality of first wirings 132 may be spaced apart from each other in the second horizontal direction (the Y direction).

A plurality of first contacts BC may be between the plurality of first vertical channels CH1 and the first wiring 132 and between the plurality of second vertical channels CH2 and the first wiring 132, respectively. Each of the plurality of first vertical channels CH1 and the plurality of second vertical channels CH2 may be electrically connected to the first wiring 132 through one first contact BC selected from among the plurality of first contacts BC.

In embodiments, each of a first vertical channel CH1 and a second vertical channel CH2 may include doped polysilicon or an oxide semiconductor material. For example, the oxide semiconductor material may include at least one metal element selected from among In, Ga, and Zn, and for example, include at least one selected from among IGZO, tin (Sn)-doped IGZO, W-doped IGZO, and IZO.

In embodiments, the first vertical channel CH1 and the second vertical channel CH2 may be formed of the same material. For example, the first vertical channel CH1 and the second vertical channel CH2 may both be formed of doped polysilicon. This may be a result of the first vertical channel CH1 and the second vertical channel CH2 being formed at the same time as part of the same process, as described below.

Each first vertical channel CH1 in a first vertical channel group may be surrounded by a second word line WL2, and each second vertical channel CH2 of a second vertical channel group may be surrounded by a third word line WL3. In a plan view, the second word line WL2 may have a plate shape surrounding each first vertical channel CH1 of a plurality of first vertical channel CH1 spaced apart from each other in the first horizontal direction (the X direction) and the second horizontal direction (the Y direction), and the third word line WL3 may have a plate shape surrounding each second vertical channel of the plurality of second vertical channels CH2 spaced apart from each other in the first horizontal direction (the X direction) and the second horizontal direction (the Y direction). The second word line WL2 and the third word line WL3 may extend lengthwise in the second horizontal direction (the Y direction).

In embodiments, each of the second word line WL2 and the third word line WL3 may include Ti, TiN, Ta, TaN, W, WN, TaSiN, WSiN, polysilicon, or a combination thereof. In embodiments, the second word line WL2 and the third word line WL3 may be formed of the same material. For example, the second word line WL2 and the third word line WL3 may be formed of Ti. This may be a result of the second word line WL2 and the third word line WL3 being formed at the same time in the same process, as described below.

The first vertical channel groups of first vertical channels CH1 and the second word line WL2 may constitute a plurality of select transistors TR2, respectively, and the second vertical channel groups of second vertical channels CH2 and the third word line WL3 may constitute a plurality of keeper transistors TR3, respectively.

A select gate insulating layer Gla may be between the first vertical channel CH1 and the second word line WL2, and a keeper gate insulating layer Glb may be between the second vertical channel CH2 and the third word line WL3. Each of the select gate insulating layer Gla and the keeper gate insulating layer Glb may be formed of, for example, at least one selected from a high-k dielectric material, which has a higher dielectric constant than silicon oxide, and a ferroelectric material.

Each of a plurality of first upper wirings 134a may be on a group of first vertical channels CH1 on each of the plurality of first wirings 132, and each of a plurality of second upper wirings 134b may be on a group of second vertical channels CH2 on each of the plurality of first wirings 132. Each of a first upper wiring 134a and a second upper wiring 134b may overlap the first wiring 132 in the vertical direction (the Z direction). Each of the first upper wiring 134a and the second upper wiring 134b may extend lengthwise in the first horizontal direction (the X direction). One first upper wiring 134a and one second upper wiring 134b above one first wiring 132 may be spaced apart from each other in the first horizontal direction (the X direction).

The first upper wirings 134a of the plurality of first upper wirings 134a may be spaced apart from each other in the second horizontal direction (the Y direction), and the second upper wirings 134b of the plurality of second upper wirings 134b may be spaced apart from each other in the second horizontal direction (the Y direction).

A plurality of second contacts DC may be between the plurality of first vertical channels CH1 and the first upper wiring 134a and between the plurality of second vertical channels CH2 and the second upper wiring 134b, respectively. Each of the plurality of first vertical channels CH1 may be electrically connected to the first upper wiring 134a through a corresponding second contact DC, and each of the plurality of second vertical channels CH2 may be electrically connected to the second upper wiring 134b through a corresponding second contact DC.

A plurality of first upper contacts 141a, a plurality of second wirings 142, and a plurality of third contacts 143 may be sequentially disposed on the plurality of first upper wirings 134a in the vertical direction (the Z direction), respectively. The plurality of first upper contacts 141a, the plurality of second wirings 142, and the plurality of third contacts 143 may overlap in the vertical direction (the Z direction), respectively.

Each of the plurality of first upper contacts 141a may have, for example, a cylindrical shape. The plurality of first upper contacts 141a may be spaced apart from each other in the second horizontal direction (the Y direction). The plurality of first upper contacts 141a may electrically connect the plurality of first upper wirings 134a to the plurality of second wirings 142, respectively, the plurality of first upper contacts 141a, the plurality of second wirings 142, and the plurality of third contacts 143 overlapping each other in the vertical direction (the Z direction), respectively.

The plurality of second wirings 142 may be spaced apart from each other in the second horizontal direction (the Y direction). One second wiring 142 may be electrically connected to one first upper wiring 134a through one first upper contact 141a. The plurality of third contacts 143 may be spaced apart from each other in the second horizontal direction (the Y direction).

A second upper contact 141b and a third wiring 144 may be sequentially on the second upper wiring 134b in the vertical direction (the Z direction). The plurality of second upper wirings 134b, a plurality of second upper contacts 141b, and one third wiring 144 may overlap in the vertical direction (the Z direction).

Each of the plurality of second upper contacts 141b may have, for example, a cylindrical shape. The plurality of second upper contacts 141b may be spaced apart from each other in the second horizontal direction (the Y direction). The plurality of second upper contacts 141b may electrically connect the plurality of second upper wirings 134b to one third wiring 144, respectively, the plurality of second upper contacts 141b, the plurality of second upper wirings 134b, and the one third wiring 144 overlapping each other in the vertical direction (the Z direction), respectively.

Compared to the second wiring 142, the third wiring 144 may extend relatively longer in the second horizontal direction (the Y direction). One third wiring 144 may overlap the plurality of second upper contacts 141b in the vertical direction (the Z direction). One third wiring 144 may be electrically connected to the plurality of second upper wirings 134b respectively corresponding to the plurality of second upper contacts 141b through the plurality of second upper contacts 141b.

A plurality of second bit lines BL2 may be on the plurality of second wirings 142 and a plurality of third wirings 144. The plurality of second bit lines BL2 may extend in the first horizontal direction (the X direction) and be spaced apart from each other in the second horizontal direction (the Y direction). A second bit line BL2 may be referred to a global bit line.

Each of the plurality of second bit lines BL2 may be electrically connected to each of the plurality of second wirings 142 respectively corresponding to the plurality of third contacts 143 through each of the plurality of third contacts 143, and accordingly, electrically connected to each the plurality of first vertical channels CH1 through each of the plurality of second wirings 142 and each of the plurality of second contacts DC. However, because no separate contacts are between the plurality of second bit lines BL2 and the third wiring 144, the second vertical channel CH2 electrically connected to the third wiring 144 may not be electrically connected to the plurality of second bit lines BL2. For example, the plurality of select transistor TR2 respectively including the plurality of first vertical channels CH1 may be connected to the second bit line BL2, but the plurality of keeper transistor TR3 respectively including the plurality of second vertical channels CH2 may not be connected to the second bit line BL2.

The second bit line BL2 may be electrically connected to components of the peripheral circuit structure SS2 to be described below. For example, the second bit line BL2 may be electrically connected to a peripheral circuit transistor 320 of the peripheral circuit structure SS2.

A plurality of first bit lines BL1 may be electrically connected to one second bit line BL2 through the plurality of first wirings 132, the plurality of first upper wirings 134a, and the plurality of second wirings 142, respectively.

In embodiments, each of the plurality of second bit lines BL2 may include any one of a doped semiconductor material, conductive metal nitride, a metal, and a metal-semiconductor compound.

In embodiments, each of the first wiring 132, the first upper wiring 134a, the second upper wiring 134b, the second wiring 142, the third wiring 144, the first contact BC, the second contact DC, the first upper contact 141a, the second upper contact 141b, and a third contact 143 may include Cu, Ru, aluminum (Al), W, molybdenum (Mo), cobalt (Co), or a combination thereof.

An upper wiring structure 150 may be on the second bit line BL2. The upper wiring structure 150 may include an upper wiring layer 152, an upper via 154, and an insulating layer 156. The upper wiring structure 150 may further include a contact 158 electrically connected to the second bit line BL2. In addition, the first bonding pad BP1 of which the upper surface is coplanar with the uppermost surface of the insulating layer 156 may be formed on the upper wiring structure 150.

The peripheral circuit structure SS2 may be on the upper wiring structure 150. The peripheral circuit structure SS2 may include a second substrate 310, the peripheral circuit transistor 320 on the second substrate 310, a front wiring structure 330 covering the peripheral circuit transistor 320 on the upper surface of the second substrate 310, and a rear wiring structure 340 on the rear surface of the second substrate 310. The front wiring structure 330 may include a front wiring layer 332, a front via 334, and a front insulating layer 336, and the rear wiring structure 340 may include a rear wiring layer 342, a rear via 344, and a rear insulating layer 346.

The second substrate 310 may include a semiconductor material, e.g., a group IV semiconductor, a group III-V compound semiconductor, or a group II-VI oxide semiconductor. For example, the group IV semiconductor may include Si, Ge, or SiGe. The second substrate 310 may be provided as a bulk wafer or an epitaxial layer. In an embodiment, the second substrate 310 may include an SOI substrate or a GeOI substrate.

The rear wiring structure 340 may include the second bonding pad BP2 of which the lower surface is coplanar with the lower surface of the rear insulating layer 346, and by connecting the second bonding pad BP2 to the first bonding pad BP1, the cell structure SS1 may be bonded to the peripheral circuit structure SS2. In embodiments, the cell structure SS1 may be attached to the peripheral circuit structure SS2 by Cu-oxide hybrid bonding. In embodiments, the second bonding pad BP2 and the first bonding pad BP1 may include Cu or a Cu alloy. The interface between the insulating layer 156 of the upper wiring structure 150 and the rear insulating layer 346 of the rear wiring structure 340 may extend flat and be coplanar with the interface between the second bonding pad BP2 and the first bonding pad BP1.

The peripheral circuit transistor 320 may include a gate electrode 322 and a gate insulating layer 324 on an active area of the second substrate 310. The peripheral circuit transistor 320 may include, for example, a sense amplifier and a sub-word line driver. The sense amplifier may be electrically connected to the second bit line BL2 included in the cell structure SS1. In addition, the sub-word line driver may be electrically connected to the plurality of first word lines WL1 included in the cell structure SS1.

The peripheral circuit structure SS2 may further include a through via 350 passing through the second substrate 310. Through the through via 350, the front wiring layer 332 included in the front wiring structure 330 may be electrically connected to the rear wiring layer 342 included in the rear wiring structure 340. In addition, the rear wiring layer 342 included in the rear wiring structure 340 may be electrically connected to the upper wiring layer 152 included in the upper wiring structure 150 through the second bonding pad BP2 and the first bonding pad BP1.

The semiconductor memory device 10 according to embodiments may include select transistors TR2, with each select transistor TR2 disposed between a respective first bit line BL1 and a respective second bit line BL2, to select the respective first bit line BL1. In this case, because the plurality of select transistors TR2 include the plurality of first vertical channels CH1, respectively, the current drivability of the plurality of select transistors TR2 may be improved, and accordingly, the electrical performance of the semiconductor memory device 10 may be improved.

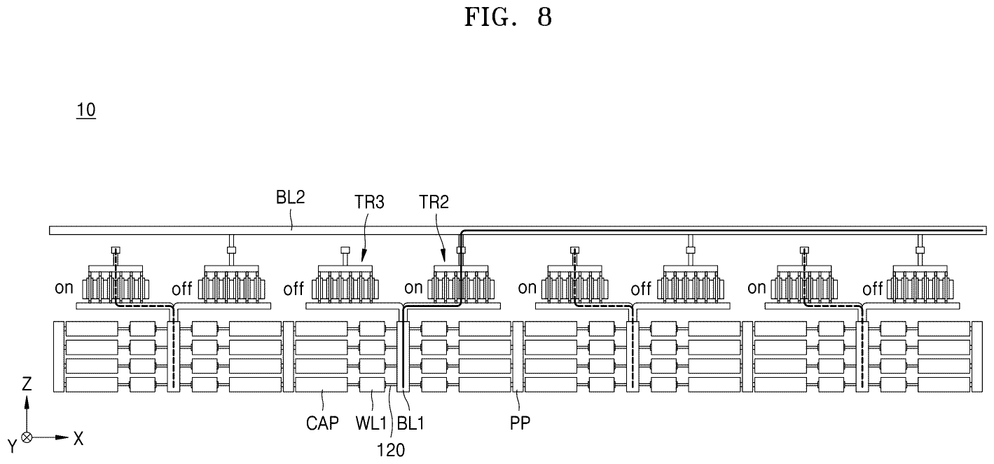

FIG. 8 is a cross-sectional view illustrating an operation of the semiconductor memory device 10 according to embodiments.

Referring to FIG. 8, a select transistor TR2, which is from among the select transistors TR2, corresponding to a first bit line BL1 connected to a first word line WL1 selected during an operation of the semiconductor memory device 10 may be turned on, and a keeper transistor TR3, which is from among the keeper transistors TR3, corresponding to the first bit line BL1 connected to the first word line WL1 selected during the operation of the semiconductor memory device 10 among keeper transistors TR3 may be turned off. Accordingly, an operating voltage may be applied to the select transistor TR2 corresponding to the first bit line BL1.

However, the remaining select transistors TR2 (e.g., all of the select transistors Tr2 except for the select transistor TR2 corresponding to the first bit line BL1) among the select transistors TR2 may be turned off, and the remaining keeper transistors TR3 (e.g., all of the keeper transistors except for the keeper transistor TR3 corresponding to the first bit line BL1) among the keeper transistors TR3 may be turned on. Accordingly, a pre-charge voltage may be applied to the remaining keeper transistors TR3 (e.g., all of the keeper transistors except for the keeper transistor TR3 corresponding to the first bit line BL1) among the keeper transistors TR3.

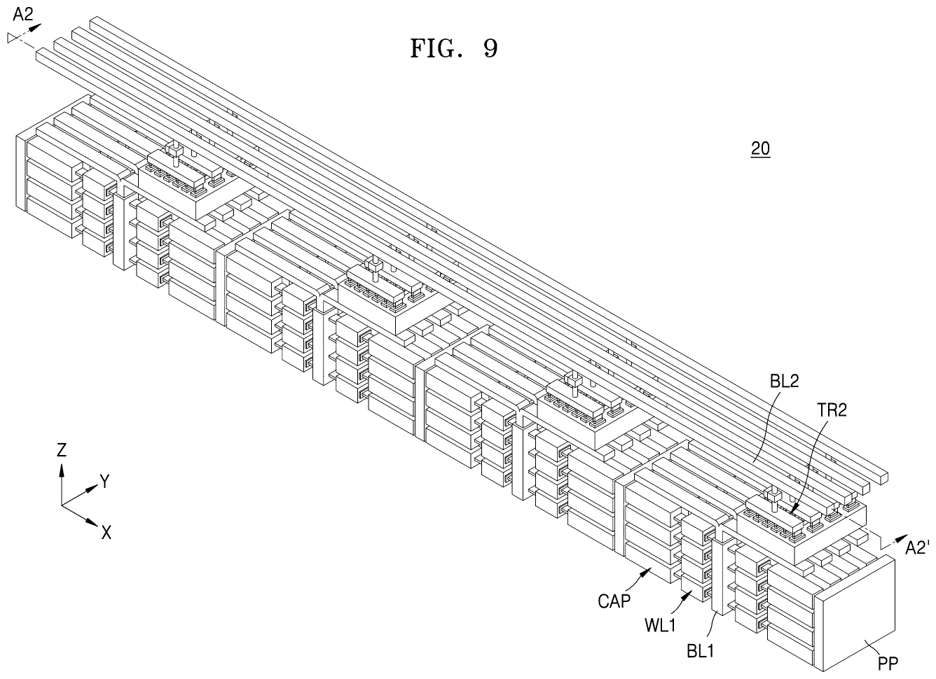

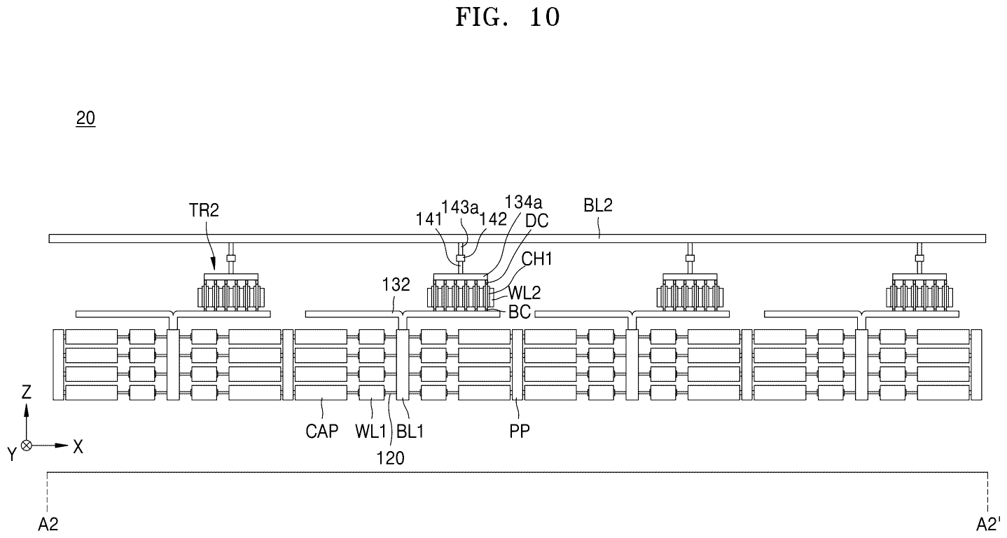

FIG. 9 is a perspective view schematically illustrating a semiconductor memory device 20 according to embodiments. FIG. 10 is a cross-sectional view taken along line A2-A2′ of FIG. 9. Because the components of the semiconductor memory device 20 illustrated in FIGS. 9 and 10 are the same or similar to the components of the semiconductor memory device 10 described with reference to FIGS. 1 to 7, differences therebetween may be mainly described hereinafter.

Referring to FIGS. 9 and 10, the semiconductor memory device 20 may have a structure similar to that of the semiconductor memory device 10 illustrated in FIGS. 1 to 7 except that the semiconductor memory device 20 does not include the keeper transistor TR3 (see FIG. 3).

The semiconductor memory device 20 may not include the keeper transistor TR3. That is, unlike the semiconductor memory device 10 illustrated in FIGS. 1 to 7, the semiconductor memory device 20 may include only the select transistors TR2.

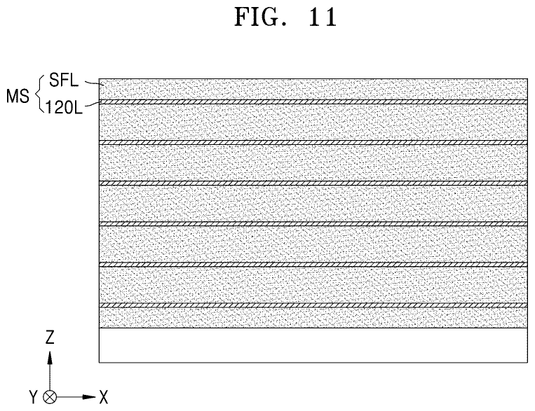

FIGS. 11 to 18 are cross-sectional views illustrating a method of manufacturing the semiconductor memory device 10, according to embodiments.

Referring to FIG. 11, a mold stack MS may be formed by alternately forming sacrificial mold layers SFL and semiconductor layers 120L on the first substrate 110.

In embodiments, each of the sacrificial mold layer SFL and the semiconductor layer 120L may be formed of a material having an etch selectivity with respect to each other. For example, each of the sacrificial mold layer SFL and the semiconductor layer 120L may be formed of a monocrystalline layer of a group IV semiconductor, a group II-VI compound semiconductor, or a group III-V compound semiconductor, and the sacrificial mold layer SFL and the semiconductor layer 120L may be formed of different materials. In some embodiments, the sacrificial mold layer SFL may be formed of SiGe, and the semiconductor layer 120L may be formed of monocrystalline Si. Each of the sacrificial mold layer SFL and the semiconductor layer 120L may have a thickness of tens of nm.

In embodiments, the sacrificial mold layers SFL and the semiconductor layers 120L may be formed by an epitaxy process. For example, the epitaxy process may include a vapor-phase epitaxy (VPE) process, a chemical vapor deposition (CVD) process, such as an ultra-high vacuum chemical vapor deposition (UHV-CVD) process, a molecular beam epitaxy process, or a combination thereof. In the epitaxy process, a liquid or gaseous precursor may be used as a precursor needed to form the sacrificial mold layers SFL and the semiconductor layers 120L.

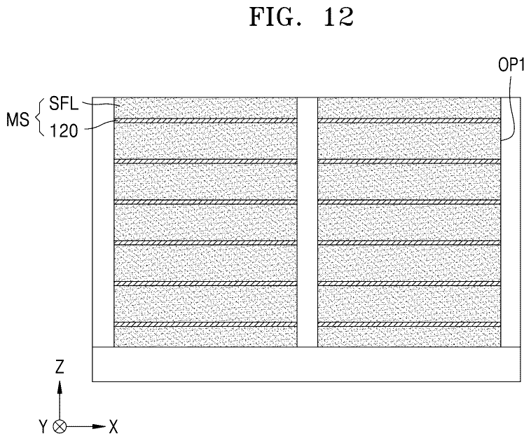

Referring to FIG. 12, a mask pattern (not shown) may be formed on the mold stack MS and used as an etching mask to remove a portion of the mold stack MS, thereby forming a first opening portion OP1. Thereafter, a first insulating layer may be formed inside the first opening portion OP1.

In embodiments, by forming the first opening portion OP1, the plurality of semiconductor patterns 120 may be formed from the semiconductor layers 120L (see FIG. 11). The plurality of semiconductor patterns 120 may be formed by patterning portions of the semiconductor layers 120L.

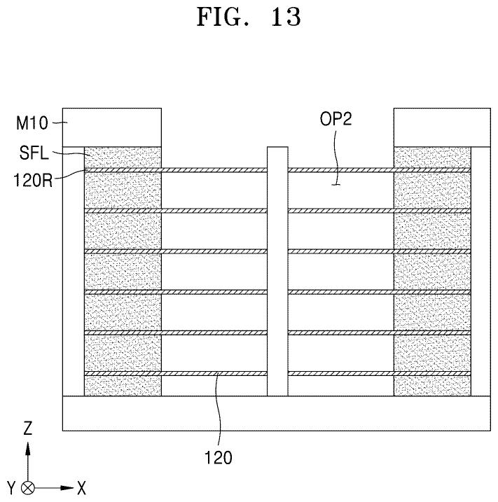

Referring to FIG. 13, a second opening OP2 may be formed between the plurality of semiconductor patterns 120 by removing the sacrificial mold layers SFL.

In some embodiments, a mask pattern M10 may be formed on the mold stack MS (see FIG. 12) to remove a portion of the sacrificial mold layer SFL uncovered by the mask pattern M10, and in this case, portions of the sacrificial mold layers SFL at positions overlapping the mask pattern M10 in the vertical direction (the Z direction) may remain without being removed. In the specification, the portions of the sacrificial mold layers SFL covered by the sacrificial mold layers SFL may be referred to as remaining patterns 120R. The mask pattern M10 may be on a structure in which the remaining patterns 120R and the sacrificial mold layer SFL are alternately stacked.

In embodiments, a process of removing the sacrificial mold layers SFL may be a wet etching process or a full back process. For example, the process of removing the sacrificial mold layers SFL may be an etching process using an etch selectivity between the sacrificial mold layer SFL and the semiconductor layer 120L (see FIG. 11). For example, in the wet etching process or the full back process, the etching speed of the plurality of semiconductor patterns 120 may be relatively low, and the etching speed of the sacrificial mold layers SFL may be relatively high.

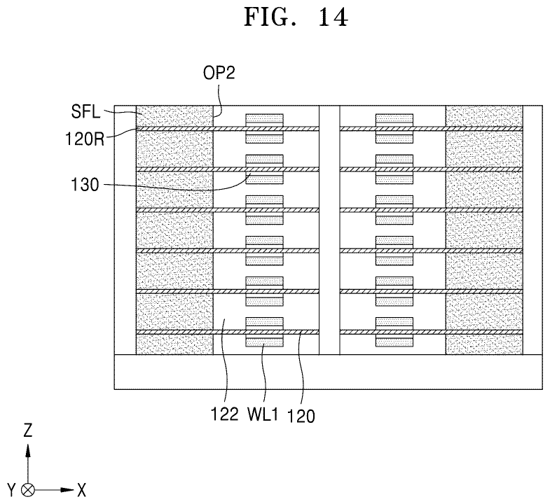

Referring to FIG. 14, inside the second opening OP2, the gate insulating layer 130 and the first word line WL1 may be sequentially formed on the upper surface, the side surface, and the lower surface of each of the plurality of semiconductor patterns 120.

For example, the gate insulating layer 130 may conformally surround each of the plurality of semiconductor patterns 120, and the first word line WL1 may extend in the second horizontal direction (the Y direction) while surrounding each of the plurality of semiconductor patterns 120 on the gate insulating layer 130.

In embodiments, inside the second opening OP2, portions of the gate insulating layer 130 and the first word line WL1 at both end portions (e.g., both end portions in the first horizontal direction (the X direction)) of each of the plurality of semiconductor patterns 120 may be removed. In some embodiments, inside the second opening OP2, a protective layer (not shown) covering both the end portions of each of the plurality of semiconductor patterns 120 may be first formed, then the gate insulating layer 130 and the first word line WL1 surrounding a central portion of each of the plurality of semiconductor patterns 120 may be formed, and then the protective layer may be removed such that both the end portions of each of the plurality of semiconductor patterns 120 are exposed again without being covered by the gate insulating layer 130 and the first word line WL1.

Thereafter, the mold insulating layer 122 filling the inside of the second opening OP2 may be formed. In some embodiments, the mold insulating layer 122 may be between two first word lines WL1 adjacent to each other in the vertical direction (the Z direction) and between end portions of two semiconductor patterns 120 adjacent to each other in the vertical direction (the Z direction).

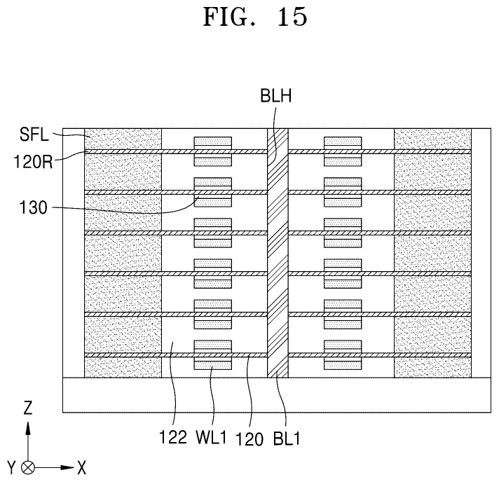

Referring to FIG. 15, a portion of the first insulating layer may be removed to form a bit line opening portion BLH, and the first bit line BL1 may be formed inside the bit line opening portion BLH.

In embodiments, two semiconductor patterns 120 may be spaced apart from each other in the first horizontal direction (the X direction) with the first bit line BL1 therebetween. That is, two semiconductor patterns 120 at the same vertical level may be electrically connected to one first bit line BL1, but the technical idea of the inventive concept is not limited thereto.

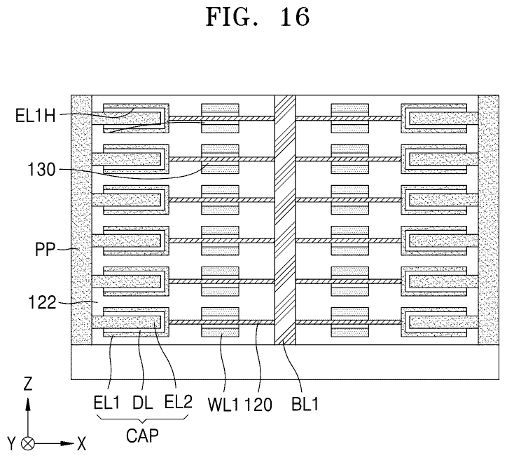

Referring to FIG. 16, the sacrificial mold layers SFL (see FIG. 15) and the remaining patterns 120R (see FIG. 15) may be removed, and the plurality of cell capacitors CAP may be formed at positions from which the sacrificial mold layers SFL (see FIG. 15) and the remaining patterns 120R (see FIG. 15) are removed.

In embodiments, the cell capacitor CAP may include the first electrode EL1, the capacitor dielectric layer DL, and the second electrode EL2. The first electrode EL1 may be electrically connected to the semiconductor pattern 120 and have an internal space EL1H extending in the first horizontal direction (the X direction). The capacitor dielectric layer DL may be conformally inside the internal space EL1H, and the internal space EL1H may be filled with the second electrode EL2.

Thereafter, the plate electrode PP electrically connected to the second electrode EL2 and extending in the second horizontal direction (the Y direction) may be formed.

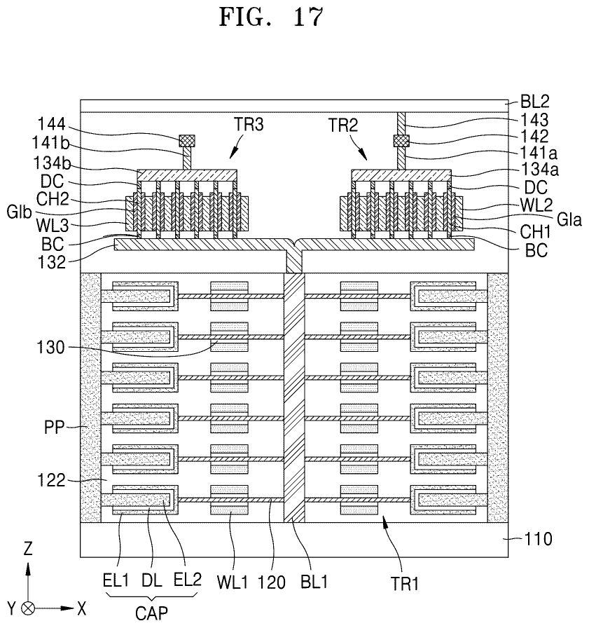

Referring to FIG. 17, first, the first wiring 132 connected to the first bit line BL1 may be formed. Thereafter, the plurality of first contacts BC may be formed on the first wiring 132, and the plurality of first vertical channels CH1, the plurality of second vertical channels CH2, the select gate insulating layer G1a, the keeper gate insulating layer G1b, the second word line WL2, and the third word line WL3 may be formed on the plurality of first contacts BC. The plurality of first vertical channels CH1 and the plurality of second vertical channels CH2 may be formed at the same time, the select gate insulating layer G1a and the keeper gate insulating layer G1b may be formed at the same time, and the second word line WL2 and the third word line WL3 may be formed at the same time. The first vertical channel CH1 and the second vertical channel CH2 may be formed by, for example, a deposition process, but the technical idea of the inventive concept is not limited thereto.

Thereafter, the second contact DC, the first upper wiring 134a, the first upper contact 141a, the second wiring 142, and the third contact 143 sequentially disposed on the first vertical channel CH1 and the second contact DC, the second upper wiring 134b, the second upper contact 141b, and the third wiring 144 sequentially disposed on the second vertical channel CH2 may be formed. The second contact DC formed on the first vertical channel CH1 and the second contact DC formed on the second vertical channel CH2 may be formed at the same time, the first upper wiring 134a formed on the first vertical channel CH1 and the second upper wiring 134b formed on the second vertical channel CH2 may be formed at the same time, the first upper contact 141a formed on the first vertical channel CH1 and the second upper contact 141b formed on the second vertical channel CH2 may be formed at the same time, and the second wiring 142 formed on the first vertical channel CH1 and the third wiring 144 formed on the second vertical channel CH2 may be formed at the same time.

Thereafter, the second bit line BL2 may be formed. The second bit line BL2 may be connected to the third contact 143.

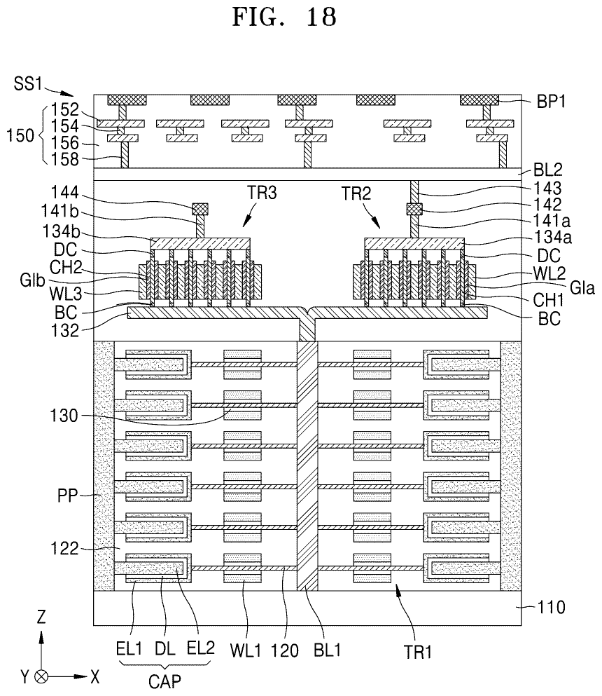

Referring to FIG. 18, the upper wiring structure 150 may be formed. The upper wiring structure 150 may include the upper wiring layer 152, the upper via 154, the insulating layer 156, and the contact 158. Thereafter, the first bonding pad BP1 of which the upper surface is coplanar with the uppermost surface of the insulating layer 156 may be formed on the upper wiring structure 150.

Thereafter, in a result of FIG. 18, the peripheral circuit structure SS2 may be prepared. The peripheral circuit structure SS2 may include the second substrate 310, the peripheral circuit transistor 320 on the second substrate 310, the front wiring structure 330 covering the peripheral circuit transistor 320 on the upper surface of the second substrate 310, and the rear wiring structure 340 on the rear surface of the second substrate 310.

In embodiments, the peripheral circuit transistor 320 may be formed on a first surface (or the upper surface) of the second substrate 310, the front wiring structure 330 may be formed on the first surface of the second substrate 310, a carrier substrate may be attached to the front wiring structure 330, and then a second surface (the lower surface) of the second substrate 310 may be grinded to make the second substrate 310 thin. Thereafter, the peripheral circuit structure SS2 may be completed by forming the rear wiring structure 340 and the second bonding pad BP2 on the second surface of the second substrate 310.

Thereafter, the peripheral circuit structure SS2 may be bonded onto the cell structure SS1. The bonding of the peripheral circuit structure SS2 and the cell structure SS1 may be performed by bonding the second bonding pad BP2 of the peripheral circuit structure SS2 to the first bonding pad BP1 of the cell structure SS1 and bonding the lower surface of the rear insulating layer 346 to the upper surface of the insulating layer 156.

While the inventive concept has been particularly shown and described with reference to embodiments thereof, it will be understood that various changes in form and details may be made therein without departing from the spirit and scope of the following claims.

What is claimed is:

1. A semiconductor memory device comprising:
a first substrate;
a semiconductor pattern disposed on the first substrate and extending in a first horizontal direction parallel to an upper surface of the first substrate;
a plurality of first word lines disposed on the first substrate and spaced apart from each other in a vertical direction;
a plurality of first bit lines extending lengthwise in the vertical direction, the first bit lines spaced apart from each other in a second horizontal direction parallel to an upper surface of the first substrate and intersecting the first horizontal direction;
a plurality of second bit lines disposed above the plurality of first bit lines, the second bit lines extending lengthwise in the first horizontal direction and spaced apart from each other in the second horizontal direction;
a plurality of select transistors, each of the select transistors interposed between a respective first bit line of the plurality of first bit lines and a respective second bit line of the second bit lines, and the select transistors spaced apart from each other in the second horizontal direction;
a plurality of first wirings interposed between the plurality of first bit lines and the plurality of select transistors, with each of the first wirings interposed between a respective one of the first bit lines and a respective one of the select transistors; and
a plurality of first upper wirings interposed between the plurality of select transistors and the plurality of second bit lines, with each of the first upper wirings interposed between a respective one of the select transistors and a respective one of the second bit lines,
wherein each of the select transistors comprises a plurality of first vertical channels.

2. The semiconductor memory device of claim 1, wherein each of the first vertical channels is connected to one first wiring selected from among the plurality of first wirings at a lower end of each of the first vertical channels and connected to one first upper wiring selected from among the plurality of first upper wirings at an upper end of each of the first vertical channels.

3. The semiconductor memory device of claim 2, wherein the one first wiring overlaps the one first upper wiring in the vertical direction.

4. The semiconductor memory device of claim 1, further comprising a second word line surrounding each of the first vertical channels.

5. The semiconductor memory device of claim 4, further comprising a select gate insulating layer interposed between the first vertical channels and the second word line.

6. The semiconductor memory device of claim 4, wherein the second word line has a plate shape surrounding the first vertical channels in a plan view.

7. The semiconductor memory device of claim 1, further comprising a plurality of first upper contacts, a plurality of second wirings, and a plurality of third contacts sequentially disposed on the plurality of first upper wirings, respectively, wherein the plurality of first upper contacts, the plurality of second wirings, and the plurality of third contacts overlap each other in the vertical direction, respectively.

8. The semiconductor memory device of claim 7, wherein the first upper contacts are spaced apart from each other in the second horizontal direction, the second wirings are spaced apart from each other in the second horizontal direction, and the third contacts are spaced apart from each other in the second horizontal direction.

9. The semiconductor memory device of claim 1, wherein first vertical channels included in one select transistor among the plurality of the select transistors are spaced apart from each other in the first horizontal direction.

10. The semiconductor memory device of claim 1, further comprising:
cell capacitors, each being connected to the semiconductor pattern and spaced apart from each other in the second horizontal direction; and
an upper wiring structure on the plurality of second bit lines and connected to each of the plurality of second bit lines.

11. A semiconductor memory device comprising:
a first substrate;
a semiconductor pattern disposed on the first substrate and extending in a first horizontal direction parallel to an upper surface of the first substrate;
a plurality of first word lines disposed on the first substrate and the first word lines spaced apart from each other in a vertical direction;
a plurality of first bit lines extending in the vertical direction and the first bit lines spaced apart from each other in a second horizontal direction intersecting the first horizontal direction;
a plurality of second bit lines disposed above the plurality of first bit lines, extending in the first horizontal direction, and the second bit lines spaced apart from each other in the second horizontal direction;
a plurality of select transistors, each of the select transistors interposed between a respective first bit line of the plurality of first bit lines and a respective second bit line of the plurality of second bit lines and spaced apart from each other in the second horizontal direction;
a plurality of keeper transistors, each of the keeper transistors interposed between a respective first bit line of the plurality of first bit lines and a respective second bit line of the plurality of second bit lines and spaced apart from other keeper transistors in the second horizontal direction;
a plurality of first wirings, each of the first wirings interposed between a respective first bit line of the plurality of first bit lines and a respective select transistor of the plurality of select transistors and between a respective first bit line of the plurality of first bit lines and a respective keeper transistor of the plurality of keeper transistors;
a plurality of first upper wirings, each of the first upper wirings interposed between a respective select transistor of the plurality of select transistors and a respective second bit line of the plurality of second bit lines; and
a plurality of second upper wirings, each of the second upper wirings interposed between a respective keeper transistor of the plurality of keeper transistors and a respective second bit line of the plurality of second bit lines,
wherein each of the select transistors comprises a plurality of first vertical channels, and each of the keeper transistors comprises a plurality of second vertical channels.

12. The semiconductor memory device of claim 11, wherein, on one first wiring selected from among the plurality of first wirings, one select transistor corresponding to the one first wiring and one keeper transistor corresponding to the one first wiring are disposed, and the one select transistor is spaced apart from the one keeper transistor in the first horizontal direction.

13. The semiconductor memory device of claim 11, further comprising:
a plurality of second wirings, each of the second wirings disposed on a respective first upper wiring of the plurality of first upper wirings; and
a third wiring disposed on the plurality of second upper wirings,
wherein the third wiring extends relatively longer than the second wirings do in the second horizontal direction.

14. The semiconductor memory device of claim 13, wherein the select transistors are electrically connected to the second wirings overlapping the select transistors in the vertical direction, respectively, and the keeper transistors are electrically connected to one third wiring.

15. The semiconductor memory device of claim 13, wherein each of the second wirings is electrically connected to a respective second bit line through a contact, and the third wiring is electrically isolated from the second bit line.

16. The semiconductor memory device of claim 11, wherein each of the first vertical channels and each of the second vertical channels are formed of the same material.

17. The semiconductor memory device of claim 11, further comprising:
a second word line surrounding each of the first vertical channels; and
a third word line surrounding each of the second vertical channels,
wherein the second word line has a plate shape surrounding the first vertical channels in a plan view, and the third word line has a plate shape surrounding the second vertical channels in a plan view.

18. The semiconductor memory device of claim 17, wherein the second word line and the third word line are formed of the same material.

19. A semiconductor memory device comprising:
a cell structure; and
a peripheral circuit structure disposed on the cell structure and bonded to the cell structure,
wherein the cell structure comprises:
a first substrate;
a semiconductor pattern on the first substrate and extending in a first horizontal direction parallel to an upper surface of the first substrate;
a plurality of first word lines disposed on the first substrate, the first word lines spaced apart from each other in a vertical direction;
a plurality of first bit lines extending in the vertical direction, the first bit lines spaced apart from each other in a second horizontal direction intersecting the first horizontal direction;
a plurality of second bit lines disposed above the plurality of first bit lines, each of the second bit lines extending in the first horizontal direction and spaced apart from other second bit lines in the second horizontal direction;
a plurality of select transistors, each of the select transistors interposed between a respective first bit line of the plurality of first bit lines and a respective second bit line of the plurality of second bit lines;
a plurality of keeper transistors, each of the keeper transistors interposed between a respective first bit line of the plurality of first bit lines and a respective second bit line of the plurality of second bit lines and spaced apart from each of the select transistors in the first horizontal direction;
a plurality of first wirings, each of the first wirings interposed between a respective first bit line of the plurality of first bit lines and a respective select transistor of the plurality of select transistors and between a respective first bit line of the plurality of first bit lines and a respective keeper transistor of the plurality of keeper transistors;
a plurality of first upper wirings, each of the first upper wirings interposed between a respective select transistor of the plurality of select transistors and a respective second bit line of the plurality of second bit lines, respectively;
a plurality of second upper wirings, each of the second upper wirings interposed between a respective keeper transistor of the plurality of keeper transistors and a respective second bit line of the plurality of second bit lines, respectively;
a plurality of second wirings, each second wiring disposed on a respective first upper wiring of the plurality of first upper wirings and electrically connected to a respective second bit line of the plurality of second bit lines;
a third wiring disposed on the plurality of second upper wirings and electrically isolated from the plurality of second bit lines; and
an upper wiring structure disposed on the plurality of second bit lines,
wherein each of the select transistors comprises a plurality of first vertical channels, and each of the keeper transistors comprises a plurality of second vertical channels.

20. The semiconductor memory device of claim 19, wherein each of the first vertical channels and each of the second vertical channels comprise doped polysilicon or an oxide semiconductor material.
